(19) United States
(12) Patent Application Publication
(10) Pub. No.: US 2015/0037588 A1
(43) Pub. Date: Feb. 5, 2015

(54) PHOTOSENSITIVE RESIN COMPOSITION, CURED PRODUCT THEREOF, AND PRINTED WIRING BOARD

(71) Applicant: Kenji Kato, Suzhou City (CN)

(72) Inventor: Kenji Kato, Suzhou City (CN)

(73) Assignee: TAIYO INK (SUZHOU) CO., LTD., Suzhou City, Jiangsu (CN)

(21) Appl. No.: 14/385,357

(22) PCT Filed: Aug. 15, 2012
(86) PCT No.: PCT/JP2012/070725

§ 371 Date: Sep. 15, 2014

(30) Foreign Application Priority Data
Mar. 23, 2012 (CN) 201210080170.6

(51) Int. Cl. G03F 7/027; B32B 37/14; C09D 163/04; C09D 133/10; C09D 163/00

(52) U.S. Cl. CPC G03F 7/027; C09D 133/10; C09D 163/00; C09D 163/04; B32B 37/14; B05D 2202/00; B32B 2255/26; B32B 2255/06
USPC 428/418; 522/39; 156/278

(57) ABSTRACT

Provided is a photosensitive resin composition which has excellent heat resistance, pore explosion resistance, empty foam resistance and crack resistance. A photosensitive resin composition of the present invention contains (A) a carboxyl group-containing resin, (B) a photopolymerization initiator, (C) a diluent solvent, (D) a compound that has two or more ethylenically unsaturated groups in each molecule and (E) a thermosetting component that has two or more cyclic ether groups and/or cyclic thioether groups in each molecule. This photosensitive resin composition is characterized in that: (A-1) a carboxyl group-containing resin which is obtained by reacting an esterified product of an epoxy group, said esterified product being produced by reacting (a) at least one kind of a bisphenol type epoxy compound and (b) an unsaturated carboxylic acid, with (c) a saturated or unsaturated polybasic acid anhydride is contained as the carboxyl group-containing resin (A); and the thermosetting component (E) has an average epoxy equivalent weight of 200 or more.

### FIELD OF TECHNOLOGY

The present invention concerns a photosensitive resin composition, and its cured product, that is suitable for the formation of solder resists on printed circuit boards and the like; in particular, it concerns a photosensitive resin composition, and its cured product, by which images can be formed by developing using ultraviolet ray exposure and dilute alkaline aqueous solution, has especially superior heat resistance, resistance to hole blowout, empty-bubble resistance, and cracking resistance, and from which a cured paint film can be obtained, as well as a printed circuit board that has such a cured product.

### BACKGROUND TECHNOLOGY

From the viewpoint of high precision and high density, what is used today for solder resists on some consumer printed circuit boards and on almost all industrial printed circuit boards are solder resists of liquid developing type, which form images by developing following exposure to ultraviolet rays and whose finishing curing (main curing) is done by heat and irradiation with light. And from considerations for environmental problems, liquid solder resists of alkali developing type that use a dilute alkaline aqueous solution as the developing solution, are in the mainstream. In wide use as alkali developing type solder resists that use such a dilute alkaline aqueous solution are liquid solder resist compositions made up of actinic energy ray curable resin in which polybasic acid anhydride is added to the reaction product of novolac type epoxy compounds and unsaturated monocarboxylic acid, photopolymerization initiators, diluents, and epoxy compounds, as described in patent reference 1.

But there has been the problem that if the above conventional liquid solder resist composition is used by specifications so as to directly fill even a circuit board that has through-holes, this could readily invite the phenomenon (called hereafter simply “empty bubbles”) in which at the time of solder leveling the area around the through-holes in the solder resist film that is formed rise up, or the phenomenon (called hereafter simply “hole blowout”) in which the paint film with which the inside of through-holes is filled is blown out post-cure or during solder leveling.

Particularly in China and the Asian region, the mainstream is circuit boards of specifications in which all the through-holes in a circuit board such as a copper through-hole circuit board are filled with a liquid solder resist composition, and solder resist compositions have been wanted that can deal with these problems of empty bubbles and hole blowout. For example, as described in patent reference 2 and patent reference 3, liquid solder resist compositions are widely known that are obtained by using together a bisphenol type resin that has photosensitivity and alkali developability, a cresol novolac type resin, and a copolymerization type resin.

Meanwhile, among copper through-hole circuit boards, according to the diameter of the through-holes, there are for example those of small-diameter specifications, such as a diameter of 200 mm or 300 mm, and those of large-diameter specifications, such as a diameter of 500 mm or 600 mm or more. With small-diameter specifications, if a conventional solder resist composition is used that has empty-bubble resistance, no problems will arise with empty bubbles or the like, but with large-diameter specifications, it is confirmed that a new problem will arise: cracking will occur in the paint film inside the through-holes at the time of sagging or solder leveler following printing. Such problems have been dealt with by specifications in which, from the fact that it causes unattractive appearance and poor reliability of the printed circuit board, after first filling in the large-diameter holes with a thermosetting composition to suppress sagging and cracking, a method is adopted of filling small-diameter holes with a conventional solder resist composition that resists empty bubbles, or filling only the large-diameter holes.

But this method of using a thermosetting composition cannot shorten the operation time and is inefficient, and with specification of filling in only the large-diameter holes, there is the fear that when applying the flux or solder, the flux or solder will go through holes and become attached to unnecessary surfaces, and this has created the possibility of causing a reduction in the reliability of the printed circuit board. Thus it is desirable to have a solder resist composition that can fill the small-diameter holes and the large-diameter holes simultaneously and excels in heat resistance, hole blowout resistance, empty-bubble resistance, and cracking resistance.

### PRIOR TECHNICAL REFERENCES

### Patent References

Patent reference 1: Unexamined patent S61-243869 [1986]

Patent reference 2: Unexamined patent 2008-116813

Patent reference 3: International publication No. 2003-059975

Patent reference 4: Unexamined patent 2002-256060

### OVERVIEW OF THE PATENT

### Problems that the Invention is to Solve

The purpose of the present invention is to provide a photosensitive resin composition, and its cured product, from which a cured paint film can be obtained that excels in heat resistance, hole blowout resistance, empty-bubble resistance, and cracking resistance, as well as a printed circuit board. Its main purpose is to provide a photosensitive resin composition that has excellent cracking resistance within large-diameter through-holes and is suitable as a solder resist composition for printed circuit boards.

More specifically, it is to provide a photosensitive resin composition that not only has the heat resistance, hole blowout resistance, and empty-bubble resistance that is demanded of a solder resist, but also has excellent cracking resistance within large-diameter through-holes, which has been insufficient in the prior art.

### Problems that the Invention is to Solve

The inventors arrived at the completion of the present invention having learned, as a result of repeated diligent research to solve the above problem, that the above problems can be solved by a photosensitive resin composition that is characterized in that it contains a carboxyl group-containing resin (A), a photopolymerization initiator (B), a dilute solvent (C), a compound (D) that has in its molecule two or more ethylenic unsaturated groups, and a thermosetting component (E) that has in its molecule two or more cyclic ether groups and/or cyclic thioether groups, as the carboxyl group-containing resin (A), it includes (A-1) a carboxyl group-containing resin that is obtained by reacting (a) at least one species of bisphenol type epoxy compound, (b) an esterification product of an epoxy group that is produced by esterification reactions with an unsaturated carboxyl group, and (c) a saturated or unsaturated polybasic acid anhydride, and the average epoxy equivalent weight of the thermosetting component (E) is 200 or more.

The photosensitive resin composition of the present invention is characterized in that it includes, as the carboxyl group-containing resin (A), (A-1) a carboxyl group-containing resin that is obtained by reacting (a) at least one species of bisphenol type epoxy compound, (b) an esterification product of an epoxy group that is produced by esterification reactions with an unsaturated carboxyl group, and (c) a saturated or unsaturated polybasic acid anhydride, and the average epoxy equivalent weight of the thermosetting component (E) is 200 or more.

With such a characteristic composition of the present invention, by the fact that it uses the carboxyl group-containing resin (A-1), which has flexibility, as the carboxyl group-containing resin (A), and that the average epoxy equivalent weight of the thermosetting component is set to 200 or more, its reactivity is made low, and as a result it is considered possible for flexibility to be given to the photosensitive resin composition, and possible to prevent cracking by relieving the stress from every direction (from all directions) that is imposed on the photosensitive resin composition inside a large-diameter through-hole for example during reflow.

In response to this, for example with a solder resist composition that has the previous empty-bubble resistance that contains only the (A-1) carboxyl group-containing resin, although empty-bubble resistance can be obtained, cracking inside large-diameter through-holes cannot be prevented. Also, with a photosensitive resin composition such as in patent reference 4, which refers to the average epoxy equivalent weight of the thermosetting component (E), the problem arises that the desired properties cannot be obtained without combining epoxy resins of various types, and that if the average epoxy equivalent weight is too large, the heat resistance will decline.

Thus with a conventional photosensitive resin composition as described above, the flexibility is insufficient, and it is difficult to bring about cracking resistance inside large-diameter through-holes.

As a result of study based on the above points, it was learned that in order to obtain cracking resistance inside large-diameter holes, it is effective to use a photosensitive resin composition that is characterized in that it has a carboxyl group-containing resin (A), a photopolymerization initiator (B), a dilute solvent (C), a compound (D) that has in its molecule two or more ethylenic unsaturated groups, and a thermosetting component (E) that has in its molecule two or more cyclic ether groups and/or cyclic thioether groups, wherein (A) includes a prepolymer obtained by reacting a saturated or unsaturated polybasic acid anhydride with the esterification product of an epoxy group produced by esterification reactions with at least one species of bisphenol type epoxy compound and unsaturated carboxylic acid, and the average epoxy equivalent weight of (E) is 200 or more.

Also, the preferred blending proportions on the components are, for every 100 parts by weight of (A), 0.01 to 30 parts by weight, and more preferably 5 to 25 parts by weight, of (B), 20 to 40 parts by weight, and more preferably 10 to 30 parts by weight, of (C), 5 to 100 parts by weight, and more preferably 1 to 70 parts by weight, of (D), and 2 to 70 parts by weight, and more preferably 10 to 50 parts by weight, of (E).

Also, the present invention offers a photosensitive resin composition, and also a printed circuit board on which circuits are formed using the photosensitive resin composition.

### EMBODIMENTS OF THE INVENTION

In the following we describe the various constituent components in the photosensitive resin composition of the present invention. It is preferable that the photosensitive resin composition of the present invention be of alkali developing type. Carboxyl group-containing resin (A)

First is (A), the carboxyl group-containing resin of the present invention; we describe the (A-1) carboxyl group-containing resin that is obtained by reacting (a) at least one species of bisphenol type epoxy compound, (b) the esterification product of an epoxy group produced by esterification reactions with an unsaturated carboxylic acid, and (c) a saturated or unsaturated polybasic acid anhydride.

What is used as the (a) at least one species of bisphenol type epoxy compound that is used in the manufacture of this (A-1) carboxyl group-containing resin is what results by using and adding, to a bisphenol A type or bisphenol F type alcoholic hydroxyl group, at least one equivalent weight, per equivalent weight of alcoholic hydroxyl group, of an epihalohydrin such as epihalohydrin or the like.

As the (b) unsaturated carboxylic acid that is added to an epoxy group of the above bisphenol type epoxy compound, we may list unsaturated dibasic acid anhydride adducts, etc. of a hydroxyl group-containing acrylate such as acrylic acid, dimers of acrylic acid, methacrylic acid, hydroxy ethyl(meth)acrylate, hydroxy propyl(meth)acrylate, hydroxy butyl(meth)acrylate, phenyl glycidyl(meth)acrylate, caprolactone(meth)acrylate adducts, etc. Particularly preferable here are acrylic acid [and] methacrylic acid. These unsaturated group-containing monocarboxylic acids may be used either singly or as a mixture.

As the (c) saturated or unsaturated polybasic acid anhydride that is reacted with an alcoholic hydroxyl group in the esterification product that is produced by esterification reactions with the bisphenol type epoxy compound and the unsaturated carboxylic acid, we may list aliphatic or aromatic dibasic acid anhydrides such as methyl tetrahydro phthalic acid anhydride, tetrahydro phthalic acid anhydride, hexahydro phthalic acid anhydride, methyl hexahydro phthalic acid anhydride, succinic acid anhydride, maleic acid anhydride, phthalic acid anhydride, itaconic acid anhydride, etc.

Also, for the quantity of this saturated or unsaturated polybasic acid anhydride to use, it is preferable to add it so that the acid value of the resulting (A-1) carboxyl group-containing resin will be within the range of 45 to 120 mgKOH/g.

Next, as other specific examples of a carboxyl group-containing resin (A), the compounds listed in the following are preferable (including their oligomers and polymers).

(1) A carboxyl group-containing photosensitive resin that is obtained by copolymerizing an unsaturated carboxyl group, such as (meth)acrylic acid, and one or more species of a compound having an unsaturated double bond other than that,

(2) a carboxyl group-containing photosensitive resin that is obtained by adding to a copolymer of an unsaturated carboxyl group, such as (meth)acrylic acid, and one or more species of a compound having an unsaturated double bond other than that, as a pendant, an ethylenic unsaturated group, by a compound that has an unsaturated double bond with an epoxy group such as glycidyl(meth)acrylate or 3,4-epoxy cyclohexyl methyl(meth)acrylate, or by a (meth)acrylic acid chloride, etc.,

(3) a carboxyl group-containing photosensitive resin that is obtained by reacting with a copolymer of an epoxy group such as glycidyl(meth)acrylate or 3,4-epoxy cyclohexyl methyl(meth)acrylate and a compound having an unsaturated double bond other than that, an unsaturated carboxyl group, such as (meth)acrylic acid, and reacting with the secondary hydroxyl group that is produced a polybasic acid anhydride,

(4) a carboxyl group-containing photosensitive resin that is obtained by reacting, with a copolymer of an acid anhydride having an unsaturated double bond, such as maleic acid anhydride, and a compound having an unsaturated double bond other than that, a compound having an unsaturated double bond with a hydroxyl group, such as 2-hydroxy ethyl(meth)acrylate,

(5) a carboxyl group-containing photosensitive resin that is obtained by reacting an unsaturated monocarboxylic acid with a polyfunctional epoxy compound, and reacting a saturated or unsaturated polybasic acid anhydride with the resulting hydroxyl group,

(6) a photosensitive resin that contains a carboxyl group and a hydroxyl group obtained by reacting a saturated or unsaturated polybasic acid anhydride with a hydroxyl group-containing polymer such as a polyvinyl alcohol derivative, then reacting with the resulting carboxylic acid a compound that has in its molecule an unsaturated double bond with an epoxy group,

(7) a carboxyl group-containing photosensitive resin that is obtained by reacting a saturated or unsaturated polybasic acid anhydride with the reaction product of a polyfunctional epoxy compound, an unsaturated monocarboxylic acid, and a compound that has in its molecule at least one alcoholic hydroxyl group and one reactive group other than an alcoholic hydroxyl group that reacts with an epoxy group,

(8) a carboxyl group-containing photosensitive resin that is obtained by reacting an unsaturated monocarboxylic acid with a polyfunctional oxetane compound that has at least two oxetane rings in its molecule, and reacting a saturated or unsaturated polybasic acid anhydride with the primary hydroxyl group in the resulting modified oxetane resin, and

(9) a carboxyl group-containing photosensitive resin that is obtained by taking a carboxyl group-containing resin that is obtained by reacting an unsaturated monocarboxylic acid with a polyfunctional epoxy resin and then reacting a polybasic acid anhydride, and further reacting with it a compound that has in its molecule one oxetane ring and at least one ethylenic unsaturated group can be listed, but there is no limitation to these.

Preferable among those listed as examples here are the carboxyl group-containing resins of the above (2), (5), (7), and (9).

Also, in this specification, “(meth)acrylate” is a generic term for acrylate, methacrylate, and their mixtures; the same is true also for other similar expressions.

Because the above carboxyl group-containing resin (A) has many free carboxyl groups on side chains of the backbone polymer, it can be developed with a dilute alkaline aqueous solution.

And the acid value of the above carboxyl group-containing resin (A) is preferably in the range 40 to 200 mgKOH/g, and more preferably in range 45 to 120 mgKOH/g. If the acid value of the carboxyl group-containing resin is less than 40 mgKOH/g, alkali developing will be difficult, and on the other hand if it exceeds 200 mgKOH/g, dissolving of the light-exposed part by the developing solution will proceed, making the lines narrower than necessary, and in some cases lead to dissolving and peeling with the developing solution with no distinction between the exposed parts and the unexposed parts, creating the undesirable outcome of making it difficult to draw normal resist patterns.

Also, the weight average molecular weight of the above carboxyl group-containing resin (A) differs depending on the resin skeleton, but generally it is preferred that it be in the range 2,000 to 150,000, and more particularly in the range 5,000 to 100,000. If the weight average molecular weight is less than 2,000, the tack-free performance after the substrate is coated and dried might be inferior, and sometimes the moisture resistance of the paint film after exposure to light will be poor, film thinning will occur during developing, and the image resolution will be large and inferior. On the other hand if the weight average molecular weight exceeds 150,000, the developability might be significantly worse, and the storage stability might be inferior.

For the blended quantity of such carboxyl group-containing resin (A), a range of 20 to 60 wt % of the entire composition is desirable, and 30 to 50 wt % is preferable. If the blended quantity of the carboxyl group-containing resin (A) is less than this range, the paint film strength may decline, which is undesirable. And if it is greater than this range, the viscosity of the composition may increase and diminish the paint film properties, which is undesirable.

Photopolymerization Initiator (B)

As photopolymerization initiators (B) that can suitably be used in the photosensitive resin composition of the present invention, we can list benzoin and benzoin alkyl ethers such as benzoin, benzoin methyl ether, benzoin ethyl ether, and benzoin isopropyl ether; acetophenones such as acetophenone, 2,2-dimethoxy-2-phenyl acetophenone, 2,2-diethoxy-2-phenyl acetophenone, 1,1-dichloro acetophenone, and 1-[4-(4-benzoyl phenyl sulfanyl)-2-methyl-2-(4-methyl phenyl sulfanyl)propane-1-one; aminoacetophenones such as 2-methyl-1-[4-(methylone)phenyl]-2-morpholino propanone-1, and 2-benzyl-2-dimethyl amino-1-(4-morpholino phenyl)-butanone; anthraquinones such as 2-methyl anthraquinone, 2-ethyl anthraquinone, 2-tertiary-butyl anthraquinone, and 1-chloro anthraquinone; thioxanthones such as 2,4-dimethyl thioxanthone, 2,4-diethyl thioxanthone, 2-chloro thioxanthone, and 2,4-diisopropyl thioxanthone; ketals such as acetophenone dimethyl ketal and benzyl dimethyl ketal; benzophenones or xanthones such as benzophenone; acyl phosphine oxides such as bis(2,6-dimethoxy benzoyl)(2,4,4-trimethyl pentyl)phosphine oxide, bis(2,4,6-trimethyl benzoyl)-phenyl phosphine oxide, 2,4,6-trimethyl benzoyl diphenyl phosphine oxide, and ethyl-2,4,6-trimethyl benzoyl phenyl phosphinate; and various types of peroxides, etc.; these well known and commonly used photopolymerization initiators may be used either singly or in combinations of two or more species.

As a preferable mode of the photopolymerization initiator (B), 2-methyl-1-[4-(methylone)phenyl]-2-morpholino porpanone-1 is used, and as commercial products, Irgacure 907, etc. made by BASF Japan can be cited.

For the blending ratio of these photopolymerization initiators (B), 0.01 to 30 parts by weight per 100 parts by weight of the aforesaid carboxyl group-containing resin (A) is suitable, and 5 to 25 parts by weight is preferred. If the quantity of photopolymerization initiator used is less than the above range, the photocurability of the composition will be bad, and if on the other hand the quantity is too great, then the properties as a solder resist will decline, making this undesirable.

Organic Solvent (C)

For the organic solvent (C) to be used in the photosensitive resin composition of the present invention, an organic solvent can be used for sake of synthesis of the carboxyl group-containing resin (A) or adjustment of the composition, or for sake of viscosity adjustment for coating the substrate or carrier film.

As such organic solvents, we can list ketones, aromatic hydrocarbons, glycol ethers, glycol ether acetates, esters, alcohols, aliphatic hydrocarbon, oil-based solvent, etc. More specifically, this includes ketones such as methyl ethyl ketone and cyclohexanone; aromatic hydrocarbons such as toluene, xylene, and tetramethyl benzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, and triethylene glycol monoethyl ether; esters such as ethyl acetate, butyl acetate, dipropylene glycol methyl ether acetate, propylene glycol methyl ether acetate, propylene glycol ethyl ether acetate, and propylene glycol butyl ether acetate; alcohols such as ethanol, propanol, ethylene glycol, and propylene glycol; aliphatic hydrocarbon such as octane and decane; and oil-based solvents such as petroleum ether, petroleum naphtha, hydrogenated petroleum naphtha, and solvent naphtha, etc. These organic solvents may be used either singly or as a mixture of two or more species.

Compound (D) that has in its molecule two or more ethylenic unsaturated groups

The compound (D) that has in its molecule two or more ethylenic unsaturated groups that is used in the photosensitive resin composition of the present invention photocures by active energy ray irradiation and makes, or helps to make, the carboxyl group-containing resin (A) insoluble in the alkaline aqueous solution. As specific examples of such compounds, we can list:

Glycol diacrylates such as ethylene glycol, methoxy tetraethylene glycol, polyethylene glycol, and propylene glycol;
Polyvalent alcohols such as hexane diol, trimethylol propane, pentaerythritol, and tris-hydroxy ethyl isocyanurate, or polyvalent acrylates such as ethylene oxide adducts or propylene oxide adducts of these;
bisphenol A diacrylate and acrylates such as ethylene oxide adducts or propylene oxide adducts of these phenols;
glycidyl ether acrylates such as glycerin diglycidyl ether, glycerin triglycidyl ether, trimethylol propane triglycidyl ether, and triglycidyl isocyanate; and
melamine acrylate and/or methacrylates that correspond to the above acrylates.

In addition, we can list epoxy acrylate resins in which acrylic acid is reacted with a polyfunctional epoxy resin such as cresol novolac type epoxy resin, and in addition, epoxy urethane acrylate compounds in which a half-urethane compound of a hydroxy acrylate such as pentaerythritol triacrylate and a diisocyanate such as isophorone diisocyanate are reacted with hydroxyl groups of their epoxy acrylate resins.

The blending quantity of such a compound (D) that has in its molecule two or more ethylenic unsaturated groups is preferably in the ratio of 5 to 100 parts by weight for every 100 parts by weight of the carboxyl group-containing resin (A), and more preferably 1 to 70 parts by weight. It is undesirable for this blending quantity to be less than 5 parts by weight for every 100 parts by weight of the carboxyl group-containing resin (A), for then the photocurability of the resulting photosensitive resin composition will decline, and it will be difficult to form patterns by alkali developing after actinic energy ray radiation. And exceeding 100 parts by weight is undesirable too, for then the solubility with respect to the alkaline aqueous solution will decline, and the paint film will become brittle.

Thermosetting Component (E)

In order to give heat resistance and cracking resistance to the photosensitive resin composition used in the present invention, there is blended in a thermosetting component (E) that has in its molecule two or more reactive groups (cyclic ether group and/or cyclic thioether group (hereafter called a cyclic (thio)ether group for short). The thermosetting component (E) of the present invention is characterized in that its average epoxy equivalent weight is 200 or more.

The epoxy equivalent weight means the numerical value obtained by dividing the molecular weight of the thermosetting component [E] by the [number of] reactive groups; in other words, it is the molecular weight per reactive group. That is, a low epoxy equivalent weight means that the thermal reactivity is high, and conversely a high epoxy equivalent weight means that the thermal reactivity is low. The average epoxy equivalent weight means the average value of the epoxy equivalent weight of the various epoxy resin. Generally, the average epoxy equivalent weight of a conventional liquid solder resist composition is 120 to 180. What is given as the reason is that using an epoxy resin of a small epoxy equivalent weight raises the thermal reactivity, and in particular it is designed for giving heat resistance to the paint film. Such a paint film of a composition that is specialized for increasing the heat resistance makes the crosslinking density high and results in a very hard paint film, so if the paint film is subjected to thermal stress load, the stress cannot be relieved, and although heat resistance can be obtained, crack resistance cannot be obtained. In the present invention, even if the average epoxy equivalent weight is set to 200 or more, the crosslinking density of the thermoset paint film can be kept low by use together with an (A-1) carboxyl group-containing resin that is obtained by reacting (a) at least one species of bisphenol type epoxy resin, (b) an esterification product of an epoxy group that is produced by esterification reactions with an unsaturated carboxylic acid, and (c) a saturated or unsaturated polybasic acid anhydride, and heat resistance and cracking resistance can be obtained by conferring flexibility.

The thermosetting component (E) is a compound that has in its molecule two or more groups, of one or two species, of a cyclic ether group or cyclic thioether group with a 3-, 4-, or 5-member ring; for example, we may list (E-1) a compound that has in its molecule at least two or more epoxy groups, that is, a polyfunctional epoxy compound, (E-2) a compound that has in its molecule at least two or more oxetanyl groups, that is, a polyfunctional oxetane compound, and (E-3) a compound that has in its molecule at least two thioether groups, that is, an episulfide resin, etc.

As the (E-1) polyfunctional epoxy compound, we can list, for example,

bisphenol A type epoxy resins such as (all brand names) jER 828, jER 834, jER 1001, and jER 1004 made by Mitsubishi Chemical Corp.; Epiclon 840, Epiclon 850, Epiclon 1050, and Epiclon 2055 made by DIC Co., YD-011, YD-013, YD-127, and YD-128 made by Tohto Kasei Co., D.E.R. 317, D.E.R. 331, D.E.R. 661, and D.E.R. 664 made by Dow Chemical Co.; Sumi-Epoxy ESA-011, ESA-014, ELA-115, and ELA-128 made by Sumitomo Chemical Co., and A.E.R. 330, A.E.R. 331, A.E.R. 661, and A.E.R. 664, made by Asahi Chemical Industry Co.;
bromated epoxy resins such as (all brand names) jERYL 903 made by Mitsubishi Chemical Corp., Epiclon 152 and Epiclon 165 made by DIC Co., Epotote YDB-400 and YDB-500 made by Tohto Kasei Co., D.E.R. 542 made by Dow Chemical Co., Sumi-Epoxy ESB-400 and ESB-700 made by Sumitomo Chemical Co., and A.E.R. 711 and A.E.R. 714 made by Asahi Chemical Industry Co.;
novolac type epoxy resins such as (all brand names) jER 152 and jER 154 made by Mitsubishi Chemical Corp., D.E.N. 431 and D.E.N 438 made by Dow Chemical Co., Epiclon N-730, Epiclon N-770, and Epiclon N-865 made by DIC Co., Epotote YDCN-701 and YDCN-704 made by Tohto Kasei Co., EPPN-201, EOCN-1025, EOCN-1020, EOCN-104S, and RE-306 made by Nippon Kayaku Co., Sumi-Epoxy ESCN-195X and ESCN-220 made by Sumitomo Chemical Co., and A.E.R. ECN-235 and ECN-299, made by Asahi Chemical Industry Co.;
bisphenol F type epoxy resins such as (all brand names) Epiclon 830 made by DIC Co., jER 807 made by Mitsubishi Chemical Corp., Epotote YDF-170, YDF-175, and YDF-2004 made by Tohto Kasei Co.;
hydrogenated bisphenol A type epoxy resins such as (brand names) Epotote ST-2004, ST-2007, and ST-3000 made by Tohto Kasei Co.;
glycidyl amino type epoxy resins such as (all brand names) jER 604 made by Mitsubishi Chemical Corp., Epotote YH-434 made by Tohto Kasei Co., and Sumi-Epoxy ELM-120 made by Sumitomo Chemical Co.;
hydantoin type epoxy resins;
alicyclic epoxy resins such as (all brand names) Celloxide 2021 and CY 179 made by Daicel Chemical Industries, Ltd.;
trihydroxy phenyl methane type epoxy resins such as (all brand names) T.E.N., EPPN-501, and EPPN-502 made by Dow Chemical Co.;
bixylenol type or biphenol type epoxy resins such as (all brand names) YL-6056, YX-4000, and YL-6121 made by Mitsubishi Chemical Corp., or mixtures thereof;
bisphenol S type epoxy resins such as (brand names) EBPS-200 made by Nippon Kayaku Co., EPX-30 made by ADEKA Co., and EXA-1514 made by DIC Co.;
bisphenol A novolac type epoxy resins such as (brand name) jER 157S made by Mitsubishi Chemical Corp.;
tetraphenylol ethane type epoxy resins such as (all brand names) YL-931 made by Mitsubishi Chemical Corp.;
heterocyclic epoxy resins such as (all brand names) TEPIC made by Nissan Chemical Industries, Ltd.;
diglycidyl phthalate resins such as Blemmer DGT made by Nippon Oil and Fats Co.; tetraglycidyl xylenoyl ethane resins such as ZX-1063 made by Tohto Kasei Co.;
naphthalene group-containing epoxy resins such as ESN-190 and ESN-360 made by Nippon Steel Chemical Co., and HP-4032, EXA-4750, and EXA-4700 made by DIC Co.;
epoxy resins having a dicyclopentadiene skeleton such as HP-7200 and HP-7200H made by DIC Co.;
glycidyl methacrylate copolymer epoxy resins such as CP-50S and CP-50M made by Nippon Oil and Fats Co.;
in addition, cyclohexyl maleimide and glycidyl methacrylate copolymer epoxy resins; epoxy-modified polybutadiene rubber derivatives (for example, PB-3600 made by Daicel Chemical Industries, Ltd., etc.) and CTBN-modified epoxy resins (for example, YR-102 and YR-450 made by Tohto Kasei Co., etc.), etc.,
but there is no limitation to these. These epoxy resins can be used either singly or in combinations of two species or more. Especially preferable among these are bisphenol A type epoxy resins and mixtures thereof.

As the (E-2) polyfunctional oxetane compounds, besides polyfunctional oxetanes such as bis[(3-methyl-3-oxetanyl methoxy)methyl]ether, bis[(3-ethyl-3-oxetanyl methoxy)methyl]ether, 1,4-bis[(3-methyl-3-oxetanyl methoxy)methyl]benzene, 1,4-bis[(3-ethyl-3-oxetanyl methoxy)methyl]benzene, (3-methyl-3oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, and oligomers or copolymers, etc. thereof, we may list oxetane alcohol and novolac resins, poly(p-hydroxy styrene), curled-type bisphenols, calixarenes, calix resorcin arenes, or etherified products with a resin that has a hydroxyl group, such as silsesquioxane. Besides these, we can also list copolymers between an alkyl(meth)acrylate and an unsaturated monomer that has an oxetane ring.

As the (E-3) compound that has in its molecule at least two cyclic thioether groups, we can list, for example, the YL 7000 bisphenol A type episulfide resin made by Mitsubishi Chemical Corp., etc. And, using a similar synthesis method, one can also use an episulfide resin in which the oxygen atom of the epoxy group of the novolac type epoxy resin is substituted with a sulfur atom.

For the blended quantity of the above thermosetting component (E) that has two or more cyclic (thio)ether groups in its molecule, the cyclic (thio)ether group is preferably 0.6 to 2.0 equivalent weights per equivalent weight of each carboxyl group of the carboxyl group-containing resin, and more preferably in the range from 0.8 to 1.5 equivalent weights. If the blended quantity of the thermosetting component having two or more cyclic (thio)ether groups in the molecule of (E) is less than 0.6, then carboxyl groups will remain in the solder resist film, lowering the heat resistance, the alkali resistance, the electrical insulation, etc., which is undesirable. On the other hand, if it exceeds 2.0 equivalent weights, then by cyclic (thio)ether groups of low molecular weight remaining in the dried paint film, the strength and other properties of the paint film will decline, which is undesirable.

If one uses a thermosetting component that has two or more cyclic (thio)ether groups in the molecule of (E) above, then it is preferred that it contain a thermosetting catalyst. As such thermosetting catalysts, we can list, for example,

imidazole derivatives such as imidazole, 2-methyl imidazole, 2-ethyl imidazole, 2-ethyl-4-methyl imidazole, 2-phenyl imidazole, 4-phenyl imidazole, 1-cyano ethyl-2-phenyl imidazole, and 1-(2-cyano ethyl)-2-ethyl-4-methyl imidazole;
amine compounds such as dicyan diamide, benzyl dimethyl amine, 4-(dimethyl amino)-N,N-dimethyl benzyl amine, 4-methoxy-N,N-dimethyl benzyl amine, and 4-methyl-N,N-dimethyl benzyl amine, and hydrazine compounds such as dihydrazide adipate and dihydrazide sebacate;
phosphorus compounds such as triphenyl phosphine, and, as commercially available items, for example, 2MZ-A, 2MZ-OK, 2PHZ, 2P4BHZ, and 2P4MHZ (all brand names of imidazole compound) made by Shikoku Chemicals Corp., U-CAT35O3N and U-CAT35O2T (both brand names of block isocyanate compounds of methyl amine) made by San'apro Co., and DBU, DBN, U-CATSA102, and UCAT5002 (all a bicyclic amidine compound or a salt thereof), etc.

There is no limitation to these in particular; as long as it is an epoxy resin or oxetane compound thermosetting catalyst, or something that promotes the reaction of a carboxyl group with an epoxy group and/or an oxetanyl group, it may be used either singly or as a mixture of two or more species. One may also use guanamine, acetoguanamine, benzoguanamine, melamine, 2,4-diamino-6-methacryloyl oxyethyl-S-triazine, 2-vinyl-2,4-diamino-S-triazine, 2-vinyl-4,6-diamino-S-triazine isocyanuric acid adducts, 2,4-diamino-6-methacryloyl oxyethyl-S-triazine isocyanuric acid adducts and other S-triazine derivatives, and preferably, a compound that also functions as an agent to cause these to adhere to each other may be used together with the thermosetting catalyst.

Other Components

In addition, as necessary, the photosensitive resin composition of the present invention may be blended with

well known and commonly used inorganic or organic fillers such as barium sulfate, barium titanate, silicon oxide powder, spherical silica, talc, clay, magnesium carbonate, calcium carbonate, aluminum oxide, aluminum hydroxide, glass fiber, carbon fiber, and mica powder;
well known and commonly used colorants such as phthalocyanine blue, phthalocyanine green, iodine green, disazo yellow, crystal violet, titanium oxide, carbon black, and naphthalene black;
well known and commonly used thermal polymerization inhibitors such as hydroquinone, hydroquinone monomethyl ether, t-butyl catechol, pyrogallol, and phenone thiazine;
well known and commonly used thickeners such as fine-powder silica, organic bentonite, and montmorillonite;
and well known and commonly used additives such as silicone, fluorine, or macromolecular anti-foaming and/or leveling agents; imidazole, thiazole, triazole, or other adhesion promotion agents or silane coupling agents, etc.

If the photosensitive resin composition of the present invention is used for solder resist formation on a printed circuit board, then after adjusting it to the proper viscosity for the coating method as necessary, it is coated onto printed circuit board on which for example a circuit pattern is formed previously, by a method such as screen printing, curtain coating, spray coating, or roll coating, and as necessary a tack-free paint film can be formed by carrying out a drying treatment at a temperature of for example, about 60 to 100° C. Thereafter, light exposure is done selectively by an active beam of light through a photomask on which the prescribed light exposure pattern is formed, and a resist pattern can be formed by developing the unexposed parts with an alkaline aqueous solution, and in addition, by for example causing thermosetting by heating to a temperature of about 140 to 180° C., the curing reactions of the thermosetting component are applied, polymerization of the light sensitive resin component is promoted, and the properties of the resulting resist film can be improved, including the heat resistance, solvent resistance, acid resistance, moisture resistance, PCT resistance, adhesiveness, and electrical properties.

As the alkaline aqueous solution to be used in the above developing, one can use an alkaline aqueous solution of potassium hydroxide, sodium hydroxide, sodium carbonate, potassium carbonate, sodium phosphate, sodium silicate, ammonia, amines, etc. And suitable as the irradiation light source for the photocuring are a low-voltage mercury lamp, a medium-voltage mercury lamp, a high-voltage mercury, an ultra-high-voltage mercury lamp, a semiconductor laser, a solid-state laser, a xenon lamp, or a metal halide lamp, etc.

### Working Examples

The present invention is described in greater detail based on working examples and comparison examples, which do not, however, limit the technical scope or implementations of the present invention. Unless otherwise specified, “parts” and “%” in the working examples and comparison examples refer to parts and percent by weight. Tests of the state values of the composition of the following working example were carried out by the techniques described in the following.

### Synthesis Example 1

Into a reaction vessel, equipped with a gas intake tube, a stirrer, a cooling tube, a thermometer, and a drip float for continuous dripping, were put 86 parts 1,4-cyclohexane dicarboxylic acid of carboxylic acid equivalent weight 86 g/equivalent weight, and 378 parts bisphenol A type epoxy resin (jER 828 made by Mitsubishi Chemical Corp., epoxy equivalent weight 189 g/equivalent weight), and in a nitrogen atmosphere it was dissolved while stirring at 110° C. Then 0.3 parts triphenyl phosphine was added, the temperature inside the reaction vessel was raided to 150° C., and while holding the temperature at 150° C., reactions were allowed to take place for about 90 minutes, yielding an epoxy compound of epoxy equivalent weight 464 g/equivalent weight. Next, the temperature inside the flask was cooled to 40° C., 390 parts carbitol acetate was added, heating and dissolving was carried out, 0.46 parts methyl hydroxynone and 1.38 parts triphenyl phosphine were added, it was heated to 95 to 105° C., 72 parts acrylic acid were slowly dripped in, and reactions were allowed to take place for 16 hours. The reaction product was cooled to 80 to 90° C., 190 parts tetrahydrophthalic acid anhydride was added, and reactions were allowed to take place for 8 hours. The carboxyl group-containing photosensitive resin that was obtained in this way has a nonvolatile portion of 65%, and an acid value of the solid parts of 100 mgKOH/g. In the following, this resin solution is called varnish A.

### Synthesis Example 2

Into a four-opening flask with a stirrer and circulation cooler was put 214 parts Epiclon 695, which is a cresol novolac type epoxy resin (made by DIC Co., epoxy equivalent weight=214), then were added 103 parts carbitol acetate and 103 parts of oil-based hydrocarbon solvent (made by Japan Energy, brand name: Cactus Fine SF-01), then heating and dissolving was done. Next, 0.1 parts hydroquinone was added as a polymerization inhibitor, and 2.0 parts triphenyl phosphine was added as a reaction catalyst. This mixture was heated to 95 to 105° C., 72 parts acrylic acid was gradually dripped in, and reactions were allowed to take place for 16 hours. The resulting reaction product was cooled to 80 to 90° C., 91.2 parts tetrahydrophthalic acid anhydride was added, reactions were allowed to take place for 8 hours, and after cooling, it was taken out. The carboxyl group-containing photopolymerization unsaturated compound that was obtained in this way had a nonvolatile component of 65% and a solids acid value of 87.5 mgKOH/g. In the following, this reaction product solution is called varnish B.

Using the carboxyl group-containing resin solutions of the above synthesis examples 1 to 2 (varnish A, varnish B), blends were made with the various components and proportions (parts by weight) shown in Table 1, and after preliminary mixing with the stirrer, kneading was done in a three-roll mill, and an alkali developing type photosensitive resin composition was prepared. Here, when the degree of dispersion of the resulting alkali developing type photosensitive resin composition was evaluated by measuring the grain size with a grind meter made by Ericsson Co., it was no greater than 5 μm.

TABLE 1
[Wex = Working example, Cex = Comparison example,
Ppi = photopolymerization initiator, Tsc = thermosetting
component]

| | Wex | Wex | Wex | Wex | Cex | Cex | Cex |
|---|---|---|---|---|---|---|---|
| | 1 | 2 | 3 | 4 | 1 | 2 | 3 |
| varnish A | 150 | 150 | 150 | 75 | | 150 | 75 |
| varnish B | | | | 75 | 150 | | 75 |
| Ppi (B-1) | 10 | 10 | 10 | 10 | 10 | 10 | 10 |
| dilute solution (C-1) | 8 | 8 | 4 | 7 | | | |
| DPHA (D-1) | 15 | 15 | 15 | 15 | 15 | 15 | 15 |
| Tsc (E-1) | | 30 | | | | | 35 |
| Tsc (E-2) | 50 | 20 | 25 | 50 | 50 | | |
| Tsc (E-3) | | | 25 | | | 50 | 15 |
| filler | 120 | 120 | 120 | 120 | 120 | 120 | 120 |
| phthalocyanine green | 1 | 1 | 1 | 1 | 1 | 1 | 1 |
| DICY | 0.4 | 0.4 | 0.4 | 0.4 | 0.4 | 0.4 | 0.4 |
| fine-powder melamine | 4 | 4 | 4 | 4 | 4 | 4 | 4 |
| silicone anti- | 3 | 3 | 3 | 3 | 3 | 3 | 3 |
| foaming agent | | | | | | | |

B-1: 2-benzyl-2-dimethyl amino-1-(4-morpholino phenyl)-butanol-1
C-1: carbitol acetate
D-1: dipentaerythritol hexaacrylate
E-1: cresol novolac type epoxy resin (made by Toho Kasei Co., brand name YDCN-704P, epoxy equivalent weight 210)
E-2: bisphenol type epoxy resin (made by Mitsubishi Chemical Corp., jER-834, epoxy equivalent weight 250)
E-2: phenol novolac type epoxy resin (made by Nippon Kayaku, RE 306, epoxy equivalent weight 178)
filler: barium sulfate (B-30 made by Sakai Chemical Industry)
DICY: dicyan diamide

Performance Evaluation:

### (1) Solder Heat Resistance

For each of the above working examples 1 to 4 and comparison examples 1 to 3, a paint film made by photocuring and thermosetting the alkali developing type photosensitive resin composition was dipped twice for 10 seconds in a solder bath at 260° C. using a rosin system and water-soluble flux according to the testing method of JIS C6481, and the state of the paint film was evaluated. The evaluation standards are as follows.

◯: no peeling or other abnormality in the paint film
X: blistering and peeling in the paint film

### (2) Hole Blowout Resistance

For each of the above working examples 1 to 4 and comparison examples 1 to 3, a paint film made by thermosetting the alkali developing type photosensitive resin composition was given a solder leveling treatment with a horizontal leveler, and the state of the paint film in the through-hole parts was observed visually. The evaluation standards are as follows.

◯: no protrusions at all of paint film in 500 through-holes of φ500
Δ: fewer than 5 protrusions of paint film in 500 through-holes of φ500
X: 5 or more protrusions of paint film in 500 through-holes of φ500

### (3) Empty-Bubble Resistance

For each of the above working examples 1 to 4 and comparison examples 1 to 3, a paint film made by thermosetting the alkali developing type photosensitive resin composition was given a solder leveling treatment with a horizontal leveler, and the state of peeling around the through-holes after a tape peel was checked. The evaluation standards are as follows.

◯: no empty bubbles at all in paint film in 500 through-holes of φ500
Δ: fewer than 5 empty bubbles in paint film in 500 through-holes of φ500
X: 5 or more empty bubbles in paint film in 500 through-holes of φ500

### (4) Cracking Resistance

For each of the above working examples 1 to 4 and comparison examples 1 to 3, a paint film made by thermosetting the alkali developing type photosensitive resin composition was given a solder leveling treatment with a horizontal leveler, and the state of the paint film in the through-hole parts was observed visually. The evaluation standards are as follows.

◯: no cracks at all of paint film in 500 through-holes of φ500
Δ: fewer than 5 cracks of paint film in 500 through-holes of φ500
X: 5 or more cracks of paint film in 500 through-holes of φ500

The above test results are presented in Table 2.

TABLE 2
[Wex = Working example, Cex = Comparison example]

| | Wex | Wex | Wex | Wex | Cex | Cex | Cex |
|---|---|---|---|---|---|---|---|
| | 1 | 2 | 3 | 4 | 1 | 2 | 3 |
| Average epoxy equivalent | 250 | 235 | 208 | 250 | 250 | 180 | 190 |
| weight | | | | | | | |
| Solder heat resistance | ◯ | ◯ | ◯ | ◯ | ◯ | ◯ | ◯ |
| Hole blowout resistance | ◯ | ◯ | ◯ | Δ | ◯ | X | ◯ |
| Empty-bubble resistance | ◯ | ◯ | ◯ | ◯ | Δ | Δ | ◯ |
| Cracking resistance | ◯ | ◯ | A | Δ | X | X | X |

As is clear from the above Table 2, it was possible to confirm that the alkali developing type photosensitive resin composition of the present invention can form a photosensitive resin composition, and its cured product, that has heat resistance, hole blowout resistance, and empty-hole resistance, and has excellent cracking resistance.

1: A photosensitive resin composition, comprising:
a carboxyl group-containing resin (A);
a photopolymerization initiator (B);
a dilute solvent (C);
a compound (D) that has in its molecule two or more ethylenic unsaturated groups; and
a thermosetting component (E) that has in its molecule two or more cyclic ether groups and/or cyclic thioether groups,
wherein the carboxyl group-containing resin (A) includes (A-1) a carboxyl group-containing resin that is obtained by reacting (a) at least one species of bisphenol type epoxy compound, (b) an esterification product of an epoxy group that is produced by an esterification reaction with an unsaturated carboxyl group, and (c) a saturated or unsaturated polybasic acid anhydride, and the thermosetting component (E) has an average epoxy equivalent weight of 200 or more.

2: A photosensitive resin composition as described in claim 1, wherein the thermosetting component (E) is a bisphenol type epoxy resin.

3: A photosensitive resin composition as described in claim 1, which is coated onto copper.

4: A photocurable dry film obtained by a process comprising coating a carrier film with a photosensitive resin composition as described in claim 1 and drying a coated carrier film.

5: A cured product obtained by a process comprising photocuring either a paint film that is obtained by coating a photosensitive resin composition as described in claim 1 onto copper and drying a coated copper, or a paint film that is obtained by laminating onto copper a photocurable dry film that is obtained by coating a carrier film with the photosensitive resin composition and drying a coated carrier film.

6: A printed circuit board, comprising:
a cured product that is obtained by photocuring and then thermosetting either a paint film that is obtained by coating a photosensitive resin composition as described in claim 1 onto a substrate and drying a coated substrate, or a paint film that is obtained by laminating onto a substrate a photocurable dry film that is obtained by coating a carrier film with the photosensitive resin composition and drying a coated carrier film.

7: A photocurable dry film obtained by a process comprising coating a carrier film with a photosensitive resin composition as described in claim 2 and drying a coated carrier film.

8: A cured product obtained by a process comprising photocuring either a paint film that is obtained by coating a photosensitive resin composition as described in claim 2 onto copper and drying a coated copper, or a paint film that is obtained by laminating onto copper a photocurable dry film that is obtained by coating a carrier film with the photosensitive resin composition and drying a coated carrier film.

9: A printed circuit board, comprising:
a cured product that is obtained by photocuring and then thermosetting either a paint film that is obtained by coating a photosensitive resin composition as described in claim 2 onto a substrate and drying a coated substrate, or a paint film that is obtained by laminating onto a substrate a photocurable dry film that is obtained by coating a carrier film with the photosensitive resin composition and drying a coated carrier film.
